(19) United States
(12) Patent Application Publication
(10) Pub. No.: US 2006/0130764 A1
(43) Pub. Date: Jun. 22, 2006

(54) Susceptor for apparatus fabricating thin film

(75) Inventor: Yong-Chun Quan, Gyunggi-do (KR)

Correspondence Address: MARGER JOHNSON & MCCOLLOM, P.C., 210 SW MORRISON STREET, SUITE 400, PORTLAND, OR, 97204, US

(73) Assignee: JUSUNG Engineering Co., Ltd., Gwangju-si (KR)

(21) Appl. No.: 11/305,389

(22) Filed: Dec. 16, 2005

(30) Foreign Application Priority Data
Dec. 16, 2004 (KR) 2004-106874
Nov. 9, 2005 (KR) 2005-106790

(51) Int. Cl. C23C 16/00

(52) U.S. Cl. 118/725; 118/728

(57) ABSTRACT

A susceptor for an apparatus fabricating a thin film on a substrate includes a body supported by a supporter therebelow; a laying groove at a top surface of the body; a temperature adjuster in the laying groove; and a cover covering the laying groove.

### BACKGROUND OF THE INVENTION

This application claims the priority of Korean Patent Application No. 2004-0106874, filed on Dec. 16, 2004, and 2005-0106790, filed Nov. 9, 2005 in the Korean Intellectual Property Office, the disclosures of which are incorporated herein in their entirety by reference.

1. Field of the Invention

The present invention relates to a susceptor for an apparatus fabricating a thin film on a substrate.

2. Background of the Related Art

Until recently, display devices have typically used cathode-ray tubes (CRTs). Presently, much effort is being expended to study and develop various types of flat panel displays, such as liquid crystal display (LCD) devices, plasma display panels (PDPs), field emission displays, and electro-luminescence displays (ELDs), as a substitute for CRTs.

These flat panel displays have a light emitting layer or a light polarizing layer on at least one transparent substrate. Recently, an active matrix type flat panel display, where a plurality of thin film transistors (TFTs) are arranged in a matrix manner, has become widely used due to high resolution and high ability of displaying moving images.

The flat panel display includes multiple thin films on a substrate. Accordingly, the flat panel display is fabricated through the repetition of a thin film-depositing process, a photolithography process, a thin film-etching process and a cleaning process. These processes are conducted in chambers having optimum environment for the corresponding processes.

FIG. 1 is a schematic cross-sectional view illustrating a PECVD (plasma enhanced chemical vapor deposition) apparatus having a susceptor according to the related art.

As illustrated in FIG. 1, the PECVD apparatus includes a chamber 10 having a reaction space, a susceptor 20 receiving a substrate 30 thereon, a gas distributing plate 40 injecting reaction gas on the substrate 20 through a plurality of injection holes 41, and a gas supply pipe 80 connected to an exterior gas reservoir (not shown) and transferring reaction gas to the gas distribution plate 40.

The gas distribution plate 40 is disposed below a plasma electrode 50 and attached to the plasma electrode 50. A buffer space 42 is defined between the gas distribution plate 40 and the plasma electrode 50. Reaction gas flowing in the buffer space 42 is firstly dispersed in the buffer space 42.

The plasma electrode 50 is connected to a RF (radio frequency) source 60 supplying a RF power. An IMP (impedance matching box) 70 is disposed between the plasma electrode 50 and the RF source 60. The susceptor 20 grounded is opposing electrode to the plasma electrode 50. The susceptor 20 may be supplied with a RF power.

The supporter 21 is connected to a bottom of a center portion of the susceptor 20 and supports the susceptor 20. A heater 90 is disposed in the susceptor 20.

The heater 90 is installed in the susceptor 20 by forming a laying groove 24 at a bottom surface of the susceptor 20, inserting the heater 90, covering the laying groove 24 with a cover 92, and welding a boundary portion between the cover 92 and the susceptor 20 to seal up the laying groove 24 tightly. Accordingly, the heater 90 is protected from reaction gas.

Since the susceptor 20 is exposed to highly corrosive reaction gas with the substrate 30 placed on the susceptor 20, a material including aluminum (Al) highly tolerant to corrosion is mainly used for the susceptor 20. Also, the cover 92 and the welding portion 94 are made the aluminum (Al), and thus deformation due to a difference between thermal expansion coefficients of the susceptor 20, the cover 92 and the welding portion 94 is prevented.

FIG. 2 is a plan view illustrating a pattern of a heater laid in a susceptor according to the related art.

As illustrated in FIG. 2, the heater 90 is laid at the entire bottom surface of the susceptor 20 such that the heater 90 heats the entire susceptor 20 uniformly.

The susceptor 20 is connected to the supporter (21 of FIG. 1) at a connection portion 22. An end of the heater 90 is protruded to the connection portion 22 and is connected to a power supply line (not shown) extended in the supporter so that the heater 90 emits heat. To protect inner electric elements from reaction gas, the connection portion 22 are sealed up such that reaction gas does not leak between the susceptor 20 and the supporter 21.

However, the related art susceptor has a problem that peripheral portions of the susceptor are warped downward.

FIG. 3 is a schematic cross-sectional view illustrating the warped susceptor according to the related art. In FIG. 3, upper and lower arrows indicates amounts of thermal expansions of the upper and lower portions, respectively.

Warping of the related art susceptor is generated by some reasons. Firstly, the laying grooves (24 of FIG. 1) and the welding portions (94 of FIG. 1) are disposed at the bottom surface of the susceptor 20. Accordingly, due to stress of the welding portion at the bottom surface of the susceptor 20, an upper portion of the susceptor 20 is thermally expanded more than a lower portion of the susceptor 20.

Further, the laying grooves as gaps are concentrated at the lower portion of the susceptor 20. Accordingly, the laying grooves absorb the thermal expansion to some extent, and thus the upper portion of the susceptor 20 is thermally expanded more than the lower portion of the susceptor 20.

Further, processes of fabricating the thin film on the substrate are conducted on the susceptor 20. Accordingly, the top surface of the susceptor 20 is directly affected by reaction gas of high temperature, and thus the upper portion of the susceptor 20 is thermally expanded more than the lower portion of the susceptor 20.

Further, the susceptor 20 has a thickness of several ten millimeters. Accordingly, due to weight of the susceptor 20, the peripheral portions of the susceptor 20 are warped downward.

Meanwhile, as size of the susceptor 20 increases, warping of the susceptor also increases. Due to warping of the susceptor, uniformity of the thin film on the substrate is degraded.

### SUMMARY OF THE INVENTION

Accordingly, the present invention is directed to a susceptor for an apparatus fabricating a thin film on a substrate that substantially obviates one or more problems due to limitations and disadvantages of the related art.

It is an object of the present invention to provide a susceptor for an apparatus fabricating a thin film on a substrate that can prevent the susceptor from being warped and improving uniformity of the thin film on the substrate.

Additional features and advantages of the invention will be set forth in the description which follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a susceptor for an apparatus fabricating a thin film on a substrate includes a body supported by a supporter therebelow; a laying groove at a top surface of the body; a temperature adjuster in the laying groove; and a cover covering the laying groove.

In another aspect, a susceptor for an apparatus fabricating a thin film on a substrate includes a first body supported by a supporter therebelow; a second body disposed on and coupled to the first body; a laying groove at one of coupling surfaces of the first and second bodies; a temperature adjuster in the laying groove; and a cover covering the laying groove.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a schematic cross-sectional view illustrating a PECVD apparatus having a susceptor according to the related art;

FIG. 2 is a plan view illustrating a pattern of a heater laid in a susceptor according to the related art;

FIG. 3 is a schematic cross-sectional view illustrating the warped susceptor according to the related art;

FIG. 4 is a cross-sectional view illustrating a susceptor according to an exemplary embodiment of the present invention;

FIG. 5 is a cross-sectional view illustrating thermal expansions of upper and lower portions of the susceptor of FIG. 4;

FIGS. 6A and 6B are exploded perspective and cross-sectional views, respectively, illustrating a susceptor according to another exemplary embodiment of the present invention;

FIG. 6C is a cross-sectional view illustrating a susceptor according to another exemplary embodiment of the present invention;

FIGS. 7A and 7B are exploded perspective and cross-sectional views, respectively, illustrating a susceptor according to another exemplary embodiment of the present invention;

FIG. 7C is a cross-sectional view illustrating a susceptor according to another exemplary embodiment of the present invention;

FIG. 8A is a cross-sectional view illustrating a susceptor according to another exemplary embodiment of the present invention;

FIG. 8B is a cross-sectional view illustrating a susceptor according to another exemplary embodiment of the present invention;

FIG. 9A is a cross-sectional view illustrating a lift pin and a lift pin hole according to another exemplary embodiment of the present invention; and

FIG. 9B is a cross-sectional view illustrating a lift pin and a lift pin hole according to another exemplary embodiment of the present invention.

### DETAILED DESCRIPTION OF THE PREFERRED EMBODIMENTS

Reference will now be made in detail to the illustrated embodiments of the present invention, which are illustrated in the accompanying drawings.

FIG. 4 is a cross-sectional view illustrating a susceptor according to an exemplary embodiment of the present invention.

As illustrated in FIG. 4, a susceptor 100 according to the exemplary embodiment has a plurality of laying grooves 101 at a top surface of the susceptor 100. Accordingly, a temperature adjuster 90 is laid in the laying grooves 101 at an upper portion of the susceptor 100.

In more detail, a susceptor body 110 of the susceptor 100 is supported by a supporter 150. The laying groove 101 is formed at the top surface of the susceptor body 110, and then the heater 90 is inserted in the laying groove 101. Thereafter, a cover 102 covers the laying groove 101 receiving the temperature adjuster 90 therein. Then, boundary portions between the cover 102 and the susceptor body 110 are welded to form a welding portion 131. In the exemplary embodiment, the heater 90 may be used for the temperature adjuster 90.

A top surface of the cover 102 may accord with the top surface of the susceptor body 110. The welding portion 131 may be planarized by grinding method such that it is not protruded from the top surface of the susceptor body 110. Accordingly, the top surface of the susceptor 100 may be even plane.

The cover 102 and the welding portion 131 may be made of the same material as the susceptor body 110 in consideration of thermal expansion. The susceptor body 110 may be made of a corrosion-proof material including aluminum (Al), and thus the cover 102 and the welding portion 131 may be made of the corrosion-proof material.

As explain above, the laying groove 101 is formed in the upper portion of the susceptor 100. Accordingly, due to stress of the welding portion 131, thermal expansion of the upper portion of the susceptor 100 is prevented to some extent. Also, since the laying grooves 101 absorb the thermal expansion of the upper portion of the susceptor 100 to some extent. Accordingly, if the upper and lower portions of the susceptor 100 have the same temperature, the upper portion has the thermal expansion less than the lower portion.

This difference between the thermal expansions of the upper and lower portions causes an upward force to peripheral portions of the susceptor 100. However, due to weight of the susceptor 100, a downward force of gravity to the peripheral portions of the susceptor 100 is caused. Also, the upper portion of the susceptor 100 has a temperature higher than that of the lower portion of the susceptor 100 because processes are conducted on the top surface of the susceptor 100. The upward force due to the laying grooves 101 disposed at the upper portion effectively compensates the downward forces due to the gravity and the temperature difference by conducting processes.

Like this, in accordance that the laying grooves 101 are formed at the upper portion of the susceptor 100, the upward and downward forces induced on the peripheral portions of the susceptor 100 can be balanced. Therefore, downward warping of the susceptor 100 can be prevented.

The laying groove 101 may be formed in an upper half of the susceptor body 110 when the susceptor body 110 is divided half and half. However, the depth of the laying groove 101 is not limited to it.

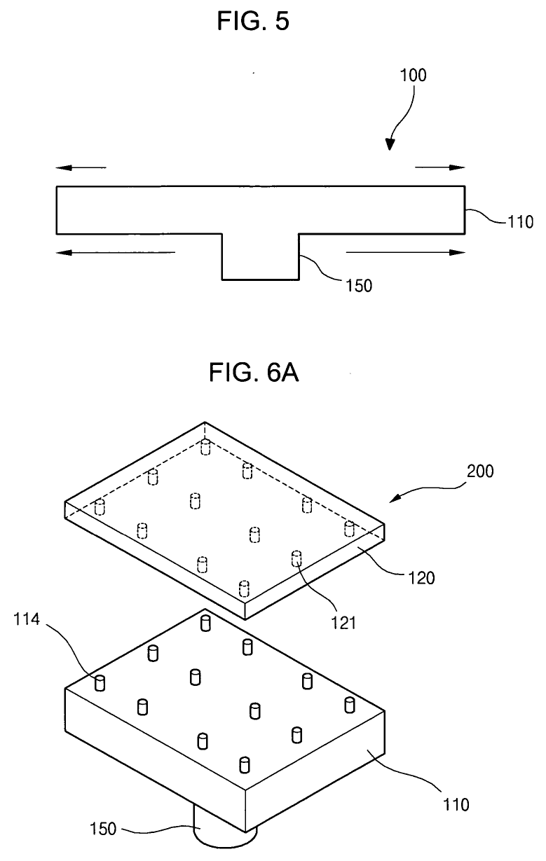

FIG. 5 is a cross-sectional view illustrating thermal expansions of upper and lower portions of the susceptor of FIG. 4. In FIG. 5, upper and lower arrows indicates amounts of thermal expansions of the upper and lower portions, respectively.

As illustrated in FIG. 5, since the laying grooves 101 are disposed in the upper portion of the susceptor body 110, the thermal expansion of the upper portion is less than that of the lower portion. Accordingly, the susceptor 100 is not warped but evenly.

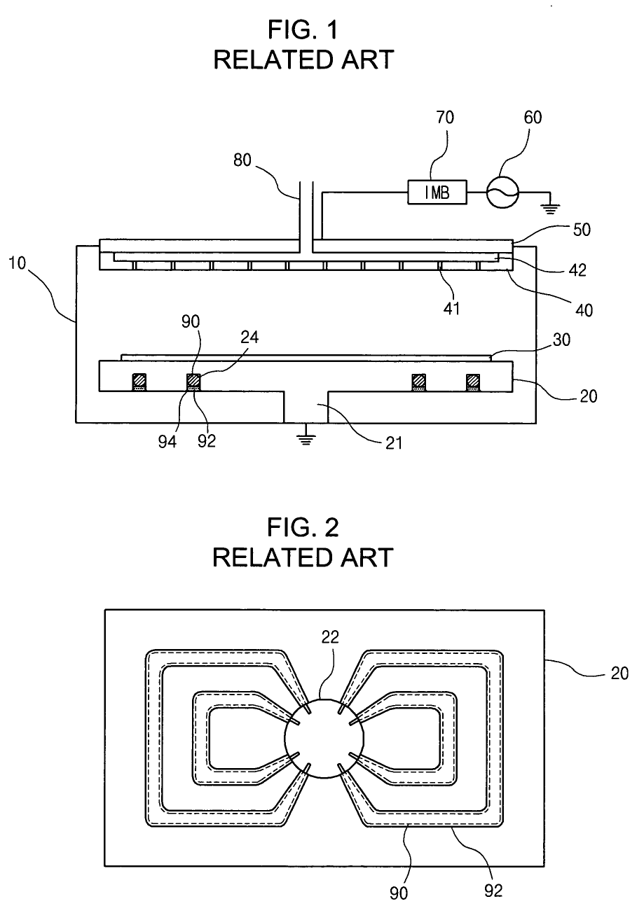

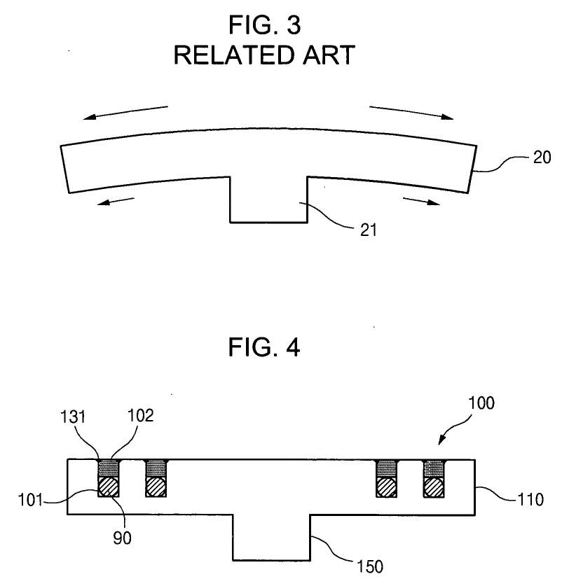

The susceptor of FIGS. 4 and 5 may have problem that drawbacks, such as damage of a substrate (30 of FIG. 1) on the susceptor, are generated because the welding portion is directly exposed to reaction gas of high temperature.

Theses problems can be resolved with following exemplary embodiments.

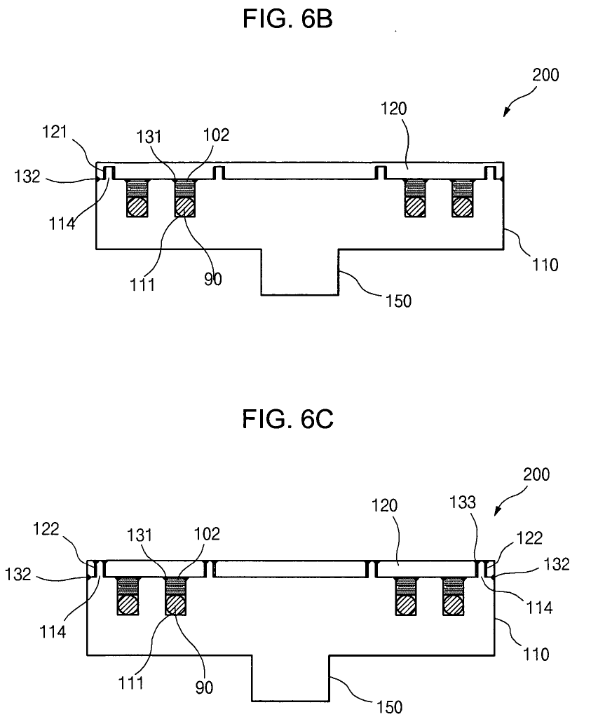

FIG. 6A and 6B are exploded perspective and cross-sectional views, respectively, illustrating a susceptor according to another exemplary embodiment of the present invention.

As illustrated in FIGS. 6A and 6B, the susceptor body includes first and second bodies 110 and 120. The first body 110 includes laying grooves 111 at a top surface of the first body 110, as similar to the susceptor body of FIG. 4, and further includes a plurality of coupling protrusions 114 on the top surface of the first body 110. Further, the second body 120 includes a plurality of coupling hollows 121 at a bottom surface of the second body 120. The coupling protrusions 114 are inserted into the corresponding coupling hollows 121 so that the first and second bodies 110 and 120 are coupled.

Similarly to the susceptor body of FIG. 4, the laying groove 111 is formed at the top surface of the first body 110, and then the heater 90 is inserted in the laying groove 111. Thereafter, a cover 102 covers the laying groove 111 receiving the heater 90 therein. Then, boundary portions between the cover 102 and the first body 110 are welded to form a first welding portion 131. Then, the first welding portion 131 is planarized.

Thereafter, the first and second bodies 110 and 120 are coupled using the coupling protrusions 114 and the coupling hollows 121, and the side portions of the first and second bodies contacting each other are welded to form a second welding portion 132. The second welding portion 132 may also be planarized.

The first and second bodies 110 and 120 may have a rectangular plane shape, however, the shape of the first and second bodies 110 and 120 is not limited. The first and second bodies 110 and 120 have the same plane shape. The first and second bodies 110 and 120 may be made of the same material.

It is required that the upper half portion of the susceptor 200 has the thermal expansion less than the lower half portion of the susceptor 200, as similar to the susceptor of FIG. 4, to prevent the peripheral portions from being warped downward. Accordingly, the second body 120 has a thin thickness to meet the requirements.

For example, a thickness from the top surface of the second body 120 to a bottom surface of the laying groove 111 may be less than a half thickness of the susceptor 200. However, it is not limited and the laying groove 111 may have more depth.

FIG. 6C is a cross-sectional view illustrating a susceptor according to another exemplary embodiment of the present invention.

As illustrated in FIG. 6C, the susceptor of FIG. 6C is similar to the susceptor of FIG. 6A, except for structures of the second body receiving the coupling protrusions of the first body. In other words, the second body 120 has a plurality of through-holes 122 going through the second body 120 vertically, as different from the coupling hollows of FIG. 6A. Accordingly, the first and second bodies 110 and 120 are coupled by inserting the coupling protrusions 114 into the coupling through-hole 122 instead of the coupling hollow of FIG. 6A.

Since the coupling protrusions 114 goes through the coupling through-hole 123 and is exposed, the coupling protrusions 114 and the second body 120 may be welded. A third welding portion 133 may be planarized. Although the third welding portion 133 is disposed at the top surface of the susceptor 200, the top surface of the susceptor of FIG. 6C has unevenness less than the top surface of the susceptor of FIG. 4 having the welding portion disposed along boundary portions of the cover.

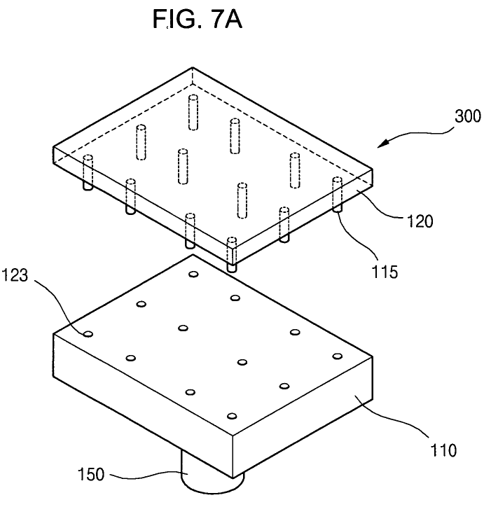

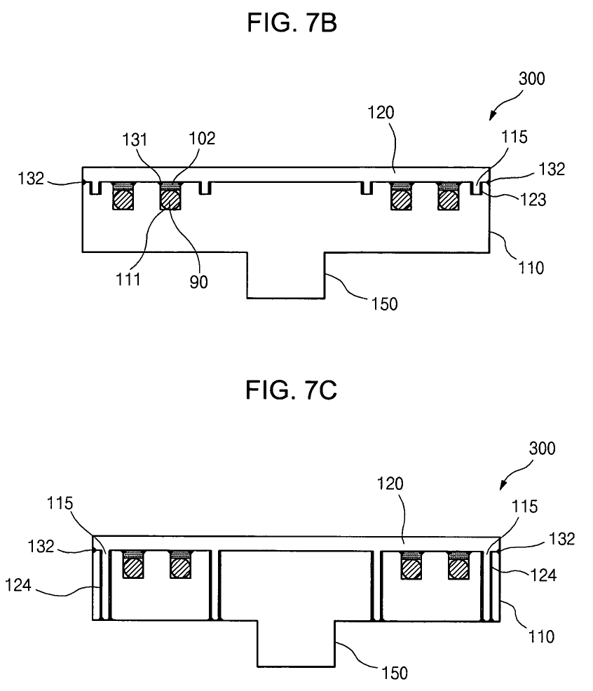

FIGS. 7A and 7B are exploded perspective and cross-sectional views, respectively, illustrating a susceptor according to another exemplary embodiment of the present invention.

As illustrated in FIGS. 7A and 7B, the susceptor 300 of FIGS. 7A and 7B is similar to the susceptor of FIGS. 6A and 6B, except for positions of coupling protrusions and coupling hollows. In other words, in the susceptor 300 of FIGS. 7A and 7B, the coupling protrusions 115 and the coupling hollows 123 are formed in the second and first bodies 120 and 110, respectively, as opposite to the susceptor of FIGS. 6A and 6B. Accordingly, the coupling protrusion 115 of the second body 120 is inserted into the coupling hollow 123 of the first body 110 so that the first and second bodies 110 and 120 are coupled.

FIG. 7C is a cross-sectional view illustrating a susceptor according to another exemplary embodiment of the present invention.

As illustrated in FIG. 7C, the susceptor 300 of FIG. 7C is similar to the susceptor of FIG. 6C, except for positions of coupling protrusions and coupling through-holes. In other words, in the susceptor 300 of FIG. 7C, the coupling protrusions 115 and the coupling through-holes 124 are formed in the second and first bodies 120 and 110, respectively, as opposite to the susceptor of FIG. 6C. Accordingly, the coupling protrusion 115 of the second body 120 is inserted into the coupling through-hole 124 of the first body 110 so that the first and second bodies 110 and 120 are coupled.

Since the coupling through-hole 124 goes through the first body 110 vertically, the coupling protrusions 115 and the first body 110 are welded at the bottom surface of the first body 110.

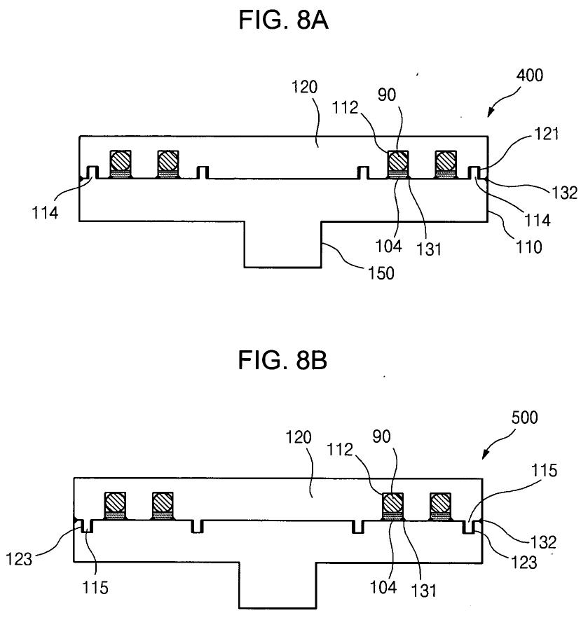

FIG. 8A is a cross-sectional view illustrating a susceptor according to another exemplary embodiment of the present invention.

As illustrated in FIG. 8A, the susceptor 400 of FIG. 8A is similar to the susceptor of FIGS. 6A and 6B, except for positions of laying grooves and heater. In other words, in the susceptor 400 of FIG. 8A, the laying grooves 112 are formed in the second body 120, as different to the susceptor of FIGS. 6A and 6B. Accordingly, the heater 90 is also disposed in the second body 120, and the cover 104 and the first welding portion 131 are also disposed in the second body 120. The coupling protrusions 114 of the first body 110 are inserted into the coupling hollows 121 of the second body 120 so that the first and second bodies 110 and 120 are coupled.

FIG. 8B is a cross-sectional view illustrating a susceptor according to another exemplary embodiment of the present invention.

As illustrated in FIG. 8B, the susceptor 400 of FIG. 8B is similar to the susceptor of FIGS. 7A and 7B, except for positions of laying grooves and heater. In other words, in the susceptor 400 of FIG. 8B, the laying grooves 112 are formed in the second body 120, as different to the susceptor of FIGS. 7A and 7B. Accordingly, the heater 90 is also disposed in the second body 120, and the cover 104 and the first welding portion 131 are also disposed in the second body 120. The coupling protrusions 115 of the second body 120 are inserted into the coupling hollows 123 of the first body 110 so that the first and second bodies 110 and 120 are coupled.

Meanwhile, the susceptors of FIGS. 8A and 8B may also have coupling through-holes instead of coupling hollows, as similar to FIGS. 6C and 7C.

In the above-described exemplary embodiments, the coupling protrusions are arranged one of the first and second bodies, whereas the coupling hollows (or coupling through-holes) are arranged in the other of the first and second bodies. However, it should be understood that the coupling members such as the coupling protrusions and coupling hollows (or coupling through-holes) may be adequately arranged in the first and second bodies.

Although not shown in FIGS. 4 to 8C, the heater 90 is connected to an exterior power source through a power supply line in the supporter 150.

The susceptors of the above-described exemplary embodiments further include a lift pin falling and raising a substrate to load and unload the substrate on the susceptor, and a lift pin through-hole going through the susceptor vertically.

If the lift pin hole is formed such that the lift pin hole goes through both the first and second bodies shown in FIGS. 6A to 8B, interference of the lift pin with the first and second bodies may be generated because of a difference between thermal expansions of the first and second bodies. Also, reaction gas may flow in the susceptor through a boundary between the first and second bodies so that inner components of the susceptor may be degraded.

Theses problems can be resolved with following exemplary embodiments.

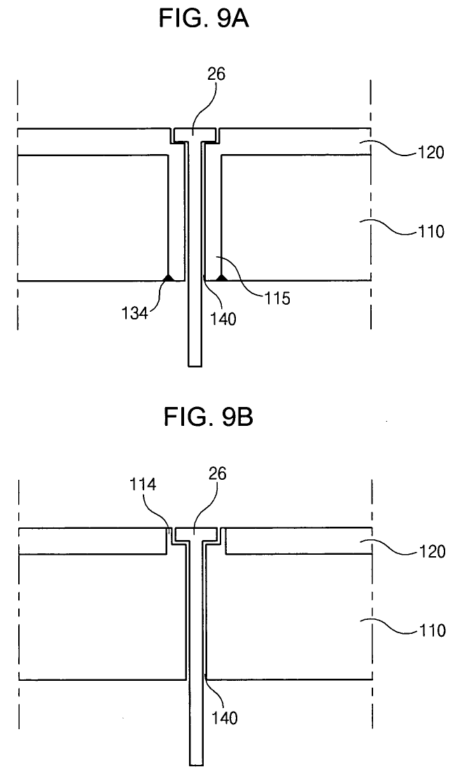

FIG. 9A is a cross-sectional view illustrating a lift pin and a lift pin hole according to another exemplary embodiment of the present invention.

As illustrated in FIG. 9A, the second body 120 of the susceptor 400 has the coupling protrusion 115 going through the first body 110 vertically, as similar to the coupling protrusion of FIG. 7C, and a though-hole defined as the lift pin hole 140 is formed in the coupling protrusion .115 The lift pin 26 is inserted into the lift pin hole 140 so that the lift pin 26 moves upward and downward. The side portion of coupling protrusion 115 is welded to the first body 110 to form a fourth welding portion 134.

FIG. 9B is a cross-sectional view illustrating a lift pin and a lift pin hole according to another exemplary embodiment of the present invention.

As illustrated in FIG. 9B, the first body 110 of the susceptor 500 has the coupling protrusion 114 going through the first body 110 vertically, as similar to the coupling protrusion of FIG. 6C, and a though-hole defined as the lift pin hole 140 is formed in the coupling protrusion 114.

In the susceptor of FIGS. 9A and 9B, the lift pin hole is formed in the coupling protrusion extended from the first body or the second body without going through both the first and second bodies. Accordingly, interference of the lift pin with the first and second bodies and inflow of reaction gas inside the susceptor can be prevented.

As explained above, in accordance that the laying grooves are laid in the upper portion of the susceptor, the upper portion of the susceptor has thermal expansion less than the lower portion of the susceptor such that the difference of the thermal expansions compensate the downward forces due to the gravity and the temperature difference due to reaction gas of high temperature. Therefore, the warping of the susceptor can be prevented and thus uniformity of thin films formed on the substrate can be improved.

The susceptor of the exemplary embodiments can be applicable to various type apparatus fabricating thin films, such as a PECVD apparatus, a CVD (chemical vapor deposition) apparatus, etcher and the like.

It will be apparent to those skilled in the art that various modifications and variations can be made in the susceptor of the present invention without departing from the spirit or scope of the invention. For instance, the present invention may also be applied to other display devices. Thus, it is intended that the present invention cover the modifications and variations of this invention provided they come within the scope of the appended claims and their equivalents.

What is claimed is:

1. A susceptor for an apparatus fabricating a thin film on a substrate, comprising:
a body supported by a supporter therebelow;
a laying groove at a top surface of the body;
a temperature adjuster in the laying groove; and
a cover covering the laying groove.

2. The susceptor according to claim 1, wherein the temperature adjuster includes a heater.

3. The susceptor according to claim 1, wherein the cover is welded to the body.

4. The susceptor according to claim 1, wherein the body is a first body and further comprising a second body disposed on and coupled to the first body.

5. The susceptor according to claim 4, wherein the first and second bodies are made of the same material.

6. The susceptor according to claim 4, wherein side portions of the first and second bodies are coupled by welding.

7. The susceptor according to claim 4, wherein the first and second bodies include first and second coupling members corresponding to each other, respectively.

8. The susceptor according to claim 7, wherein one of the first and second coupling members includes a coupling protrusion, and the other of the first and second coupling members includes a coupling hollow.

9. The susceptor according to claim 7, wherein one of the first and second coupling members includes a coupling protrusion, and the other of the first and second coupling members includes a coupling through-hole.

10. The susceptor according to claim 9, wherein the coupling protrusion has a lift pin hole therein receiving a lift pin.

11. The susceptor according to claim 9, wherein the coupling protrusion is welded to one of the first and second bodies having the corresponding coupling through-hole.

12. The susceptor according to claim 3, wherein the welding portion is even.

13. A susceptor for an apparatus fabricating a thin film on a substrate, comprising:
a first body supported by a supporter therebelow;
a second body disposed on and coupled to the first body;
a laying groove at one of coupling surfaces of the first and second bodies;
a temperature adjuster in the laying groove; and
a cover covering the laying groove.
